(19) United States
(12) Patent Application Publication
(10) Pub. No.: US 2017/0133342 A1
(43) Pub. Date: May 11, 2017

(54) Bond Wire Connection

(71) Applicant: NXP B.V., Eindhoven (NL)

(72) Inventors: Wiwat Tanwongwan, Chatuchak (TH); Piyarat Suwannakha, Bangkok (TH); Chanon Suwankasab, Pathumthani (TH)

(21) Appl. No.: 15/339,594

(22) Filed: Oct. 31, 2016

(30) Foreign Application Priority Data
Nov. 6, 2015 (EP) 15193403.1

(51) Int. Cl. H01L 23/00; H01L 21/56; H01L 21/48; H01L 23/495; H01L 23/31

(52) U.S. Cl. CPC H01L 24/48; H01L 23/49503; H01L 23/49541; H01L 23/3114; H01L 21/4825; H01L 24/85; H01L 21/565; H01L 2924/3512; H01L 2224/48095; H01L 2224/48245; H01L 2224/48472; H01L 2224/48465; H01L 2224/85047

(57) ABSTRACT

An integrated circuit package is provided. The integrated circuit package comprises: a die; a lead; and a bond wire comprising a first end coupled to the die and a second end coupled to the lead via bond. The bond wire further comprises: a first portion between a first bend in the bond wire and the bond and forming a first angle with respect to the lead; and a second portion forming a second angle with respect to the lead. The first bend is immediately between the first and second portions and is configured to reduce the angle of the bond wire with respect to the lead from the second angle to the first angle.

### CROSS-REFERENCE TO RELATED APPLICATIONS

This application claims the priority under 35 U.S.C. §119 of European patent application no. 15193403.1, filed Nov. 5, 2015 the contents of which are incorporated by reference herein.

### FIELD

The present disclosure relates to wire bonding in integrated circuit packages and in particular, but not exclusively to, wedge bonding of bond wires between a die and a lead.

### BACKGROUND

An integrated circuit package may be formed by encapsulating a die and portion of a lead frame using a compound such as an epoxy mold compound. Before encapsulation, the die may be coupled to leads of the lead frame via one or more bond wires forming a loop between the die and the leads. The bond wires can be bonded to the lead using wire bonding. One method of wire bonding is wedge bonding. In wedge bonding, the bond wire may be applied to the lead using ultrasonic.

The integrated circuit package may be tested to determine whether it adheres to minimum standards. A subset of these tests may include stress tests such as a life-time test, which may cause or exacerbate cracks in the wedge bonds. In some cases the cracks may be caused by delamination of wedge bond which may be a product of the different thermal properties of the different material in and around the wedge bond.

Wedge bond cracks may affect the operation of the integrated circuit in some applications. Additionally some packages may be have to have minimum reliability to meet customer requirements.

### SUMMARY

According to a first aspect, there is provided an integrated circuit package comprising: a die; a lead; and a bond wire comprising a first end coupled to the die and a second end coupled to the lead via a bond; the bond wire further comprising: a first portion between a first bend in the bond wire and the bond and forming a first angle with respect to the lead; a second portion forming a second angle with respect to the lead; wherein the first bend is immediately between the first and second portions and is configured to reduce the angle of the bond wire with respect to the lead from the second angle to the first angle.

The first angle may be equal to or less than 10°. The bond wire may further comprise a third portion coupled between the second portion and the die. The two or more portions of the bond wire may be integral. The first bend may be formed by bending the bond wire in a direction opposite to the direction in which the lead lies relative to the bond wire. The bond wire may comprise at least one further bend between the first end of the bond wire and the first bend, the further bend configured to form at least part of a loop between the first end and the first bend. The bond may be one of a wedge bond and a stitch bond.

According to a second aspect, there is provided a method for coupling an integrated circuit die to a lead comprising: coupling a first end of a bond wire to an integrated circuit die; providing a first bend in the bond wire immediately between a first portion of the bond wire and a second portion of the bond wire; coupling a second end of the bond wire to a lead using a bond; wherein: the first portion of the bond wire is between the first bend and the bond and forms a first angle with respect to the lead; the second portion forms a second angle with respect to the lead; and the first bend is configured to reduce the angle of the bond wire with respect to the lead from the second angle to the first angle.

Providing the first bend may further comprise bending the bond wire in a direction opposite to the direction in which the lead lies with respect to the bond wire. The bond wire may further comprise a third portion coupled between the second portion and the die. The method may further comprise: providing at least one further bend between the first end of the bond wire and the first bend, the further bend configured to form at least part of a loop between the first end and the first bend. The bond may be one of a wedge bond and a stitch bond.

According to a third aspect, there is provided an integrated circuit package comprising: a die; a lead; and a plurality of bond wires, each bond wire comprising a first end coupled to the die and a second end coupled to the lead via a bond; the plurality of bond wires each further comprising: a first portion between a first bend in the bond wire and the bond and forming a first angle with respect to the lead; a second portion forming a second angle with respect to the lead; wherein the first bend is immediately between the first and second portions and is configured to reduce the angle of the bond wire with respect to the lead from the second angle to the first angle.

The integrated circuit package may further comprise: a further terminal; and a plurality of further bond wires, each further bond wire comprising a first end coupled to the die and a second end coupled to the further lead via a bond; the plurality of further bond wires each further comprising: a first portion between a first bend in the further bond wire and the bond and forming a first angle with respect to the further lead; a second portion forming a second angle with respect to the further lead; wherein the first bend is immediately between the first and second portions and is configured to reduce the angle of the further bond wire with respect to the lead from the second angle to the first angle.

The respective first ends of the plurality of bond wires may be coupled to a first terminal of the die and the respective first ends of the plurality of further bond wires may be coupled to a second terminal of the die.

### FIGURES

Embodiments will be described, by way of example only, with reference to the drawings, in which:

FIG. 1 is a schematic diagram showing an integrated circuit package;

FIG. 2; is a schematic diagram showing an integrated circuit package according to a first embodiment;

FIG. 3 is an enlarged view of a portion of FIG. 2;

FIGS. 4a, 4b, 4c, 4d and 4e are schematic diagrams, each showing a configuration of a bond wire according to further embodiments; and

FIG. 5 is a flow diagram depicting the method steps of some embodiments.

### DESCRIPTION

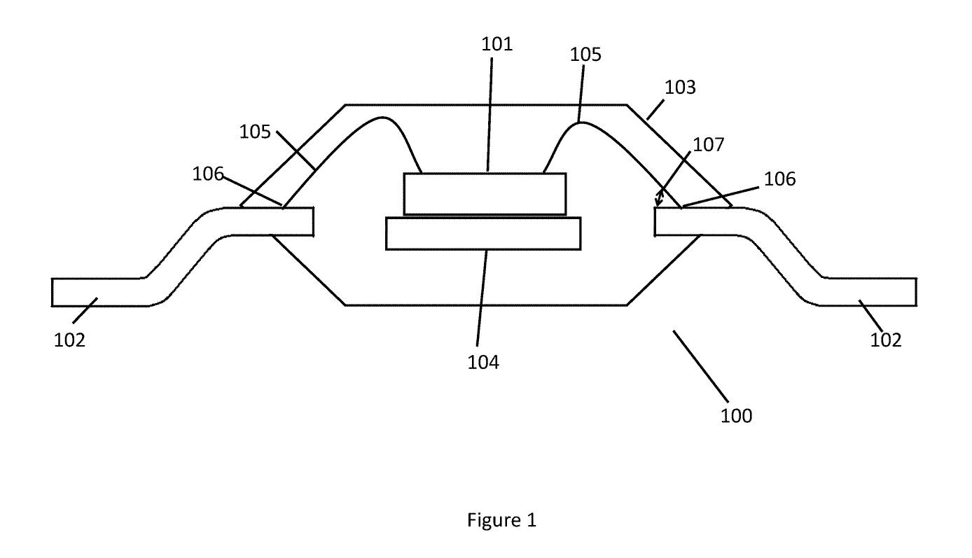

FIG. 1 shows an example of an integrated circuit package 100. The integrated circuit package 100 comprises an integrated circuit die 101, and a lead frame comprising a leads 102 and a lead frame pad 104 on which the die 101 can be mounted. Bond wires 105 are provided to couple the die 101 to the leads 102. The bone wires 105 may be coupled to the leads 102 using a wedge bond 106. The bond wires 105 may be at an angle 107 with respect to the leads 102 at which a wedge bond is formed. The package may be formed by encapsulating the die 101, lead frame pad 104, bond wires 105 and portion of the leads 102 on which the wedge bond 106 is formed to provide a body 103.

The wedge bonds 106 of the integrated circuit package 101 of FIG. 1 may be susceptible to wedge bond cracks. In particular these cracks may form when the integrated circuit package is subject to stress, for example mechanical or thermal stress. It will be appreciated that the presence of wedge bond cracks may adversely affect the reliability of the package 100 and may make it unsuitable for some applications.

The present disclosure addresses the formation of wedge bond cracks by adapting the configuration of a bond wire coupled between the die and lead. In particular, the bond wire is configured to comprise a first bend between a first and second portion of the bond wire, which is configured to reduce and angle between the bond wire and the lead for the portion of the bond wire between the first bend and the wedge bond.

The inventors of the present disclosure have recognized that an angle at which the bond wire meets the lead may affect the surface area of the lead contacted by the bond wire. When the bond wire does not entirely contact the surface of the lead, a gap may be left which is subsequently filled by the encapsulating material, for example an epoxy mold compound. In this situation, the wedge bond may be cracked during stress because of the different thermal expansion of the encapsulating material in the gap to the bond wire/wedge bond.

In the present disclosure, the angle at which the bond wire meets the lead is adjusted by introducing a first bend into the bond wire. The bond wire may make contact with an area of the lead preventing a gap in which the encapsulating material may enter.

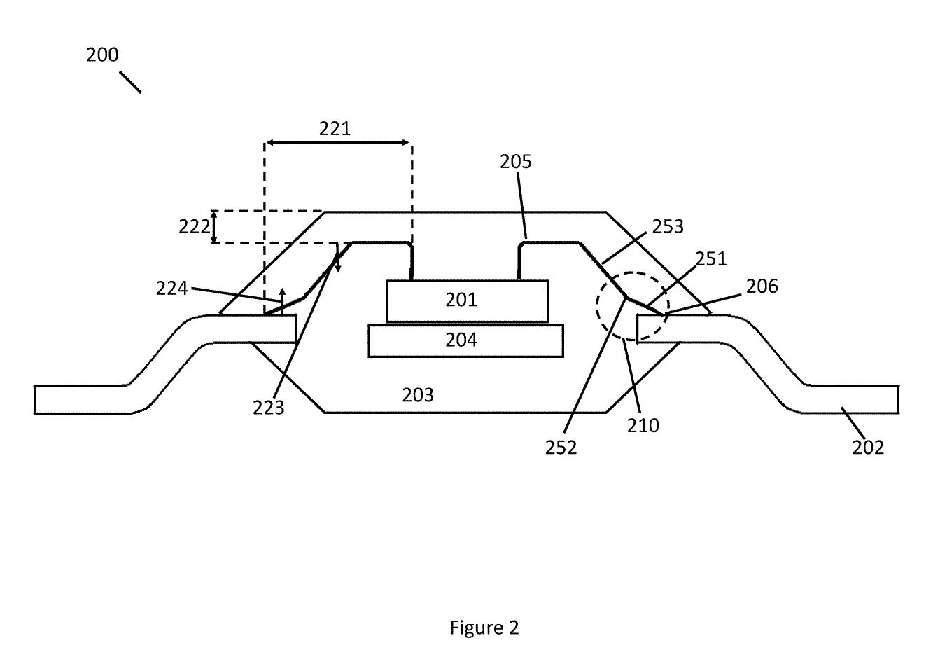

FIG. 2 is an example of an integrated circuit package 200 in accordance with some embodiments. The integrated circuit package 200 comprises a die 201 which may be mounted to a lead frame pad 204, a lead 202 and a package body 203. A bond wire 205 is coupled between the die 201 and the lead 202. The bond wire may be coupled to the lead via a wedge bond 206. A first portion 251 of the bond wire may be defined between the wedge bond 206 and a first bend 252 in the bond wire. The first bend 252 may lie immediately between the first portion 251 of the bond wire 205 and a second portion 253 of the bond wire.

It will be appreciated that in FIG. 2, the configuration of the integrated circuit package 200 is mirrored with the right and left halves of the figure having different labels. It will be appreciated that this is done for clarity only and all reference numerals can equally refer to their mirrored counterpart.

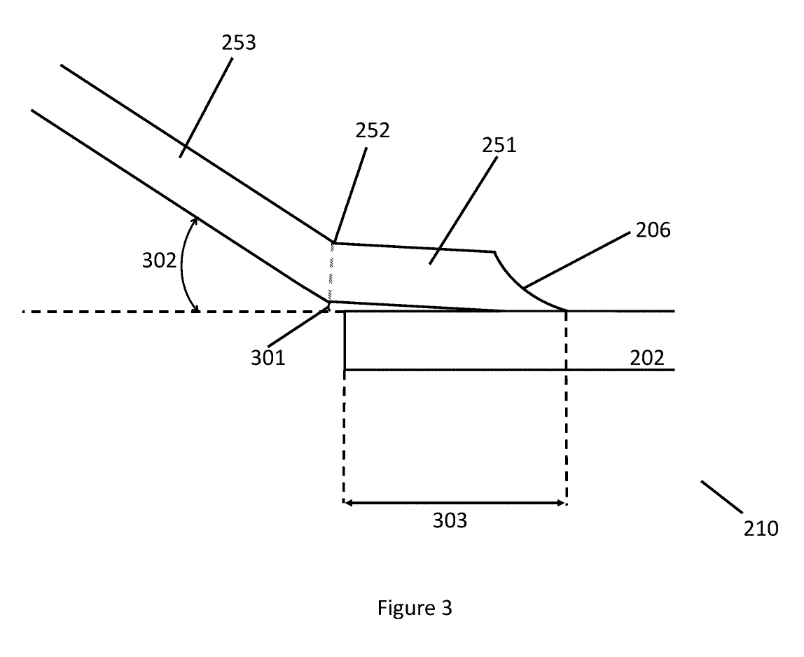

The first portion 251 of the bond wire may be positioned having a first angle with respect to the lead. The second portion may be positioned having a second angle with respect to the lead. The first bend 252 may be provided in the bond wire 205 to reduce the angle between the bond wire 205 and the lead. In this case, the first bend 252 reduces the angle between the bond wire and the lead from the second angle to the first angle. The area of the bond wire and lead indicated by 210 in FIG. 2 is shown enlarged in FIG. 3.

FIG. 3 shows a portion 210 of the integrated circuit die 200. The portion 210 of the integrated circuit die 200 comprises a portion of the lead 202, the wedge bond 206, the first portion 251 of the bond wire, the second portion 253 of the bond wire and the first bend 252. A first angle 301 between the bond wire at the first portion 251 and the lead is shown. A second angle 302 between the bond wire at the second portion 253 and the lead is shown.

From FIG. 3, it can be seen that the first bend 252 changes the orientation of the bond wire 205 with respect to the lead in order to reduce the angle between the bond wire 205 and the lead from the second angle 302 to the first angle 301. This angle 302, 301 may be reduced with the introduction of the first bend 252. The first bend 252 may be immediately provided between the second portion 253 and the first portion 251. The first portion 251 may be provided between the wedge bond and the first bend 252. The majority of the length of the first portion 251 may be aligned with the lead 202, in other words the majority of the first portion 251 may lie above the lead 202. In this manner, the first bend 252 may be in the vicinity of an edge of the lead 202.

In one example, the relationship between the bond wire 205 and the integrated circuit package 200 may be given by a variety of parameters. In this example, a distance 303 between the wedge bond 206 and the edge of the lead is shown in FIG. 3. Referring back to FIG. 2, a distance 221 between a point coupling the bond wire to the die and the wedge bond of that bond wire is shown. A distance 222 is additionally shown between the top surface of the integrated circuit package body 203 and a highest point of the bond wire 205 is shown.

It will be appreciated that, in some embodiments, these parameters may have set values, however this will be dependent on the application of the package 200 and thus are by way of example only.

In one example, the parameters may have values according to the following table.

TABLE 1

| Parameter | Dimension |
|---|---|
| 222 - Distance from top of body 203 to | More than 0.0125 mm |
| closest point of bond wire 205 | |
| 221 - Distance between first end of bond | More than 0.270 mm |
| wire coupled to die and second end of | |
| bond wire wedge bonded to lead | |
| 302 - Second angle φ | Not over 45 degrees |
| 301 - First angle θ | Not over 10 degrees |
| 303 - Distance between wedge bond and | x, where x = y/tanθ |
| edge of lead | and y = the distance between |
| | the first portion and the lead |

It will be appreciated that table 1 shows only one example of the values that may be implemented. It will further be appreciated that the first and second angles 301 and 302 may not be dependent on the other parameters. In particular the first and second angles 301 and 302 may take on the values of table 1 without requiring that the other parameters also do so.

FIG. 2 further shows a first direction away from the lead 202 depicted by arrow 224 and a second direction towards the lead depicting by arrow 223. It will be appreciated that in order to reduce the angle between the bond wire 205 and the lead 202, the first bend 252 may be provided by bending the bond wire 205 in a direction away from the lead as shown by 224. It will also be appreciated that providing the first bend 252 may provide the first and second portions 251 and 253.

The shape of the bond wire between the coupling point to the die and the first bend 252 (which may include the second portion 253) may be provided in a variety of configurations. FIG. 2 shows one example of this configuration however it will be appreciated that other configurations are possible.

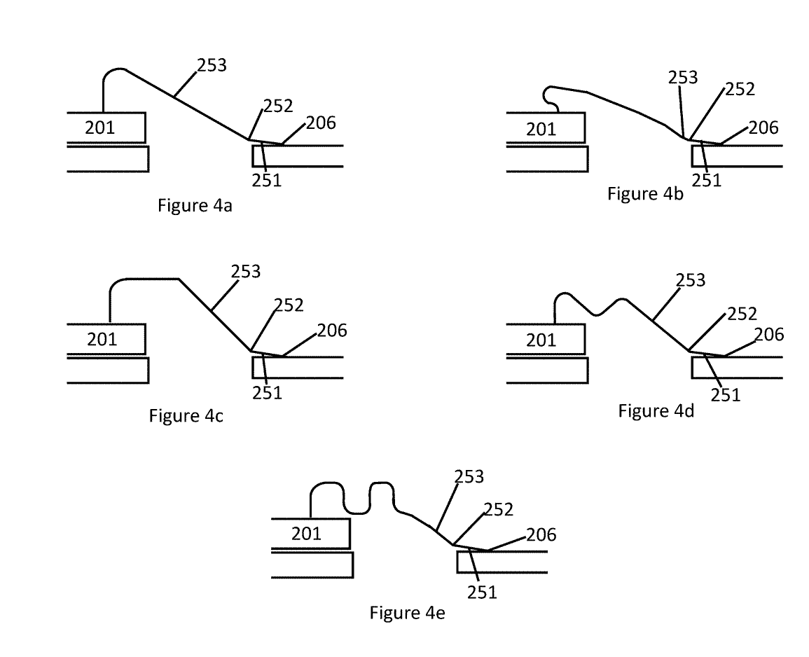

FIGS. 4a to 4e show various configurations of the portion of the bond wire 205 between the first bend 251 and the die 201. It will be appreciated that in each configuration there is at least one second bend in the bond wire 205. It will be appreciated that these are by way of example only and the configuration of the bond wire 205 between the die 201 and the first bend 251 may take any suitable form. For example, this configuration may be dependent on the application of the die 201, the packaging in which the die 201 is to be implemented and/or the type of tool used to place the bond wire 205.

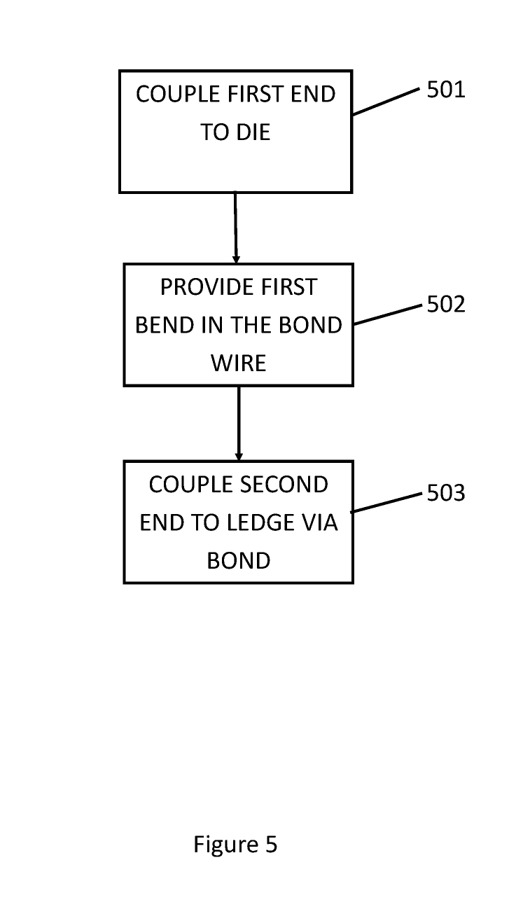

It will appreciated that the configuration of the bond wire 205 may be provided in the manufacture of the integrated circuit die. FIG. 5 shows an example of the method steps that may be carried out when coupling a bond wire between an integrated circuit die and lead.

At step 501, a bond wire is coupled to a die. It will be appreciated that the coupling may take place using any suitable means. For example, the bond wire may be wedge bonded to the die using ultrasonic bonding or, alternatively for example be stitch bonded to the die. In some examples, the bond wire may be directly coupled or attached to die, in other examples the bond wire may be coupled to the die via a bonding medium.

At step 502, a first bend may be provided in the bond wire. In some embodiments, the first bend may be provided by the wire bonding tool used to carry out the ultrasonic bonding. The bonding tool may guide the bond wire from the die to the lead and may form a loop shape in the bond wire. Some examples of the loop shape are given in FIGS. 4a to 4e. The first bend may be provided between a first portion of the bond wire and a second portion of the bond wire. The second portion of the bond wire may lie between the first bend and the die. The first portion of the bond wire may lie between the first bend on the wedge bond to the lead.

The first bend may change the angle between the bond wire and the lead from an angle between the second portion of the bond wire and the lead to an angle between the first portion of the bond wire and the lead. The first bend may change the angle by reducing the angle. In some examples, the first bend may be provided by bending the bond wire in a direction opposite to the direction in with the plane in which the lead is provided lies with respect to the bond wire. In other words, the bond wire may be bent away from the bottom or lead frame plane of the package.

After the first bend, the angle between the lead and the first portion of the bond wire may be reduced. In a specific example, the bonding tool may form a loop of bond wire between the die and lead. A second portion of the bond wire (corresponding to the second portion 253) may be formed having an angle of just less than 45 degrees between the second portion and the lead. More generally, the second portion may have an angle of more than 10 degrees, but not more than 45 degrees. The first bend may adjust this angle. For example, the angle between the lead and the first portion of the bond wire between the first bend and the lead may be equal to or less than 10 degrees. The bonding tool may then bond the bond wire to the lead at step 503. It may do so by creating a wedge bond between the first portion of the bond wire and the lead using ultrasonic bonding.

The reduced angle between the first portion of the bond wire and the lead may allow the first portion of the bond wire to contact the surface area of the lead when pressure is applied to it by the bonding tool. This may decrease a gap between the first portion of the bond wire and the lead when compared to a bond wedge of a bond wire having a larger angle between the bond wire and the lead.

In the foregoing a first angle 301 and a second angle 302 have been discussed. It will be appreciated that the second angle may be less than or equal to 90° and the first angle may fall within between 0° and the second angle 302. It will also be appreciated that the bond wire may further comprise at least second bend between the second portion of the bond wire and the first end of the bond wire. This second bend may be configured to orientate the bond wire 205 away from the die and towards the lead.

In the foregoing, the bond between the bond wire 205 and the lead (tail end of the bond wire) is described as being a wedge bond 206 however it will be appreciated that any suitable bond may be used. For example a stitch bond may be used in place of the wedge bond in some examples.

In the foregoing, the bonding of a single bond wire between a die and a lead has been described. It will however be appreciated that an integrated circuit package may comprise a plurality of bond wire and embodiments may be applicable to the plurality of bond wires.

The described embodiments are to be considered in all respects only as illustrative and not restrictive. The scope of the invention is, therefore, indicated by the appended claims rather than by this detailed description. All changes that come within the meaning and range of equivalency of the claims are to be embraced within their scope.

Reference throughout this specification to features, advantages, or similar language does not imply that all of the features and advantages that may be realized with the present invention should be or are in any single embodiment. Rather, language referring to the features and advantages is understood to mean that a specific feature, advantage, or characteristic described in connection with an embodiment is included in at least one embodiment. Thus, discussions of the features and advantages, and similar language, throughout this specification may, but do not necessarily, refer to the same embodiment.

One skilled in the relevant art will recognize, in light of the description herein, that the invention can be practiced without one or more of the specific features or advantages of a particular embodiment. In other instances, additional features and advantages may be recognized in certain embodiments that may not be present in all embodiments of the invention.

1. An integrated circuit package comprising:
a die;
a lead; and
a bond wire comprising a first end coupled to the die and a second end coupled to the lead via a bond;
the bond wire further comprising:
a first portion between a first bend in the bond wire and the bond and forming a first angle with respect to the lead;
a second portion forming a second angle with respect to the lead;
wherein the first bend is immediately between the first and second portions and is configured to reduce the angle of the bond wire with respect to the lead from the second angle to the first angle.

2. The integrated circuit of claim 1 wherein the first angle is equal to or less than 10°.

3. The integrated circuit of claim 1 wherein the bond wire further comprises a third portion coupled between the second portion and the die.

4. The integrated circuit of claim 1 wherein the two or more portions of the bond wire are integral.

5. The integrated circuit of claim 1 wherein the first bend is formed by bending the bond wire in a direction opposite to the direction in which the lead lies relative to the bond wire.

6. The integrated circuit of claim 1 where the bond wire comprises at least one further bend between the first end of the bond wire and the first bend, the further bend configured to form at least part of a loop between the first end and the first bend.

7. The integrated circuit of claim 1 wherein the bond is one of a wedge bond and a stitch bond.

8. A method for coupling an integrated circuit die to a lead comprising:
coupling a first end of a bond wire to an integrated circuit die;
providing a first bend in the bond wire immediately between a first portion of the bond wire and a second portion of the bond wire;
coupling a second end of the bond wire to a lead using a bond;
wherein:
the first portion of the bond wire is between the first bend and the bond and forms a first angle with respect to the lead;
the second portion forms a second angle with respect to the lead; and
the first bend is configured to reduce the angle of the bond wire with respect to the lead from the second angle to the first angle.

9. The method of claim 8 wherein providing the first bend further comprises bending the bond wire in a direction opposite to the direction in which the lead lies with respect to the bond wire.

10. The method of claim 8 wherein the bond wire further comprises a third portion coupled between the second portion and the die.

11. The method of claim 8 further comprising: providing at least one further bend between the first end of the bond wire and the first bend, the further bend configured to form at least part of a loop between the first end and the first bend.

12. The method of claim 8 wherein the bond is one of a wedge bond and a stitch bond.

13. An integrated circuit package comprising:
a die;
a lead; and
a plurality of bond wires, each bond wire comprising a first end coupled to the die and a second end coupled to the lead via a bond;
the plurality of bond wires each further comprising:
a first portion between a first bend in the bond wire and the bond and forming a first angle with respect to the lead;
a second portion forming a second angle with respect to the lead;
wherein the first bend is immediately between the first and second portions and is configured to reduce the angle of the bond wire with respect to the lead from the second angle to the first angle.

14. The integrated circuit package of claim 13 further comprising:
a further terminal; and
a plurality of further bond wires, each further bond wire comprising a first end coupled to the die and a second end coupled to the further lead via a bond;
the plurality of further bond wires each further comprising:
a first portion between a first bend in the further bond wire and the bond and forming a first angle with respect to the further lead;
a second portion forming a second angle with respect to the further lead;
wherein the first bend is immediately between the first and second portions and is configured to reduce the angle of the further bond wire with respect to the lead from the second angle to the first angle.

15. The integrated circuit package of claim 13 wherein the respective first ends of the plurality of bond wires are coupled to a first terminal of the die and the respective first ends of the plurality of further bond wires are coupled to a second terminal of the die.
